(19) United States
(12) Patent Application Publication
(10) Pub. No.: US 2025/0285871 A1
(43) Pub. Date: Sep. 11, 2025

(54) METHOD OF MANUFACTURING SEMICONDUCTOR DEVICE AND SEMICONDUCTOR DEVICE MANUFACTURING APPARATUS

(71) Applicant: Mitsubishi Electric Corporation, Tokyo (JP)

(72) Inventors: Daisuke CHIKAMORI, Tokyo (JP); Katsuhisa SAKAI, Tokyo (JP); Naoyoshi SHIRAISHI, Fukuoka (JP); Kosuke KOBASHI, Tokyo (JP)

(73) Assignee: Mitsubishi Electric Corporation, Tokyo (JP)

(21) Appl. No.: 19/002,576

(22) Filed: Dec. 26, 2024

(30) Foreign Application Priority Data
Mar. 11, 2024 (JP) 2024-037298

(51) Int. Cl. H01L 21/304; H01L 21/683

(52) U.S. Cl. CPC H01L 21/304; H01L 21/6835; H01L 2221/68327

(57) ABSTRACT

A method includes a step of applying a viscous material to a front surface having asperities thereon of a semiconductor wafer, a step of curing the viscous material, and a step of grinding a back surface of the semiconductor wafer on which the cured viscous material has been provided, a reference surface and projections constitute the asperities on the front surface, and a variation in distance between a surface of the cured viscous material and the reference surface is 15% or less of an in-plane average of the distance in the front surface of the semiconductor wafer. A fractured layer after grinding of the back surface can thereby be thinned, so that a fracture strength of the semiconductor wafer can be increased.

### BACKGROUND OF THE INVENTION

### Field of the Invention

The present disclosure relates to a method of manufacturing a semiconductor device and a semiconductor device manufacturing apparatus and, in particular, to thinning of a semiconductor wafer.

### Description of the Background Art

In fields such as memory and microprocessors, packages have increasingly been densified due to three-dimensional implementation of semiconductor devices and the like. This is accompanied by an increasing need for thinning of semiconductor wafers.

In inverter circuits mounted to compressor motors of air conditioners, vehicle motors, and the like and submarine DC transmission, for example, a power semiconductor device mainly handling a relatively large power of several hundred kilowatts to several megawatts is sometimes used. An example of the power semiconductor device includes a semiconductor switch, such as a diode, metal-oxide-semiconductor field-effect transistor (MOSFET), and an insulated gate bipolar transistor (IGBT).

In the manufacture of such a power semiconductor device, a semiconductor wafer is thinned to improve current-carrying characteristics, such as an on resistance. In thinning of the semiconductor wafer, mechanical grinding (polishing), such as back grinding and polishing, and chemical surface treatment, such as wet etching and dry etching, to remove an affected layer resulting from mechanical grinding are generally performed.

In mechanical grinding (polishing), breakage of the semiconductor wafer sometimes occurs during grinding of a back surface of the semiconductor wafer due to asperities on a front surface of the semiconductor wafer. Due to recent progress of thinning of a semiconductor device, the proportion of a height difference of the asperities to the thickness of the semiconductor device as a whole has been increased. Planarization of the front surface of the semiconductor wafer thus becomes more and more important in mechanical grinding (polishing). While there are various methods of planarizing the front surface, one of the methods is a method of applying a resin to a surface having the asperities thereon of the semiconductor wafer.

As one example, WO 2022/190916 discloses a method of applying a resin to a front surface of a semiconductor wafer using a dispenser, stacking a support base on a surface of an uncured resin, and curing the resin while holding the stacked state to planarize a surface of a resin layer.

The method disclosed in WO 2022/190916, however, requires stacking of the support base on the surface of the uncured resin and has a problem in that a semiconductor device is costly to manufacture.

### SUMMARY

It is an object of the present disclosure to provide a method of manufacturing a semiconductor device and a semiconductor device manufacturing apparatus that enable reduction in cost.

A method of manufacturing a semiconductor device according to the present disclosure includes: an application step of applying a viscous material to a first main surface of a wafer, the first main surface having an asperity thereon, the wafer having the first main surface and a second main surface opposite the first main surface; a curing step of curing the viscous material; and a grinding step of grinding the second main surface of the wafer. A reference surface corresponding to a surface of the wafer orthogonal to a direction of a thickness of the wafer and a projection from the reference surface constitute the asperity on the first main surface. A variation in distance between a surface of the cured viscous material and the reference surface is 15% or less of an in-plane average of the distance in the first main surface.

A method of manufacturing a semiconductor device according to the present disclosure includes: an application step of applying a viscous material to a first main surface of a wafer, the first main surface having an asperity thereon, the wafer having the first main surface and a second main surface opposite the first main surface; a curing step of curing the viscous material; and a grinding step of grinding the second main surface of the wafer. The application step includes a first application step of applying the viscous material to a recess of the asperity and a second application step of applying the viscous material to the first main surface after the first application step.

A semiconductor device manufacturing apparatus according to the present disclosure includes: a stage on which a wafer is mounted; a dispenser disposed to face the stage; and a housing covering a discharge portion of the dispenser and the stage. The wafer has a first main surface having an asperity thereon and a second main surface opposite the first main surface, and the second main surface of the wafer is mounted on the stage. The dispenser applies a viscous material to the first main surface with the wafer being mounted on the stage. The housing has an opening through which the discharge portion is inserted to face the stage and further has an air outlet at a different location from the opening.

According to the method of manufacturing the semiconductor device and the semiconductor device manufacturing apparatus according to the present disclosure, a cost in the manufacture of the semiconductor device can be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart showing a method of manufacturing a semiconductor device according to Embodiment 1;

FIG. 2 is a schematic cross-sectional view illustrating a state of a semiconductor wafer in step S1;

FIG. 3 is a schematic cross-sectional view illustrating a state of the semiconductor wafer in step S4;

FIG. 4 is a scanning electron microscopy image showing a cross section of the semiconductor wafer in step S4;

FIG. 5 is a schematic perspective view of an application apparatus according to Embodiment 1;

FIG. 6A is a schematic cross-sectional view illustrating a state of the semiconductor wafer in step S4, and FIG. 6B is a schematic cross-sectional view illustrating a state of the semiconductor wafer in step S4 in another example;

FIG. 7 is a schematic cross-sectional view illustrating a state of the semiconductor wafer in step S5;

FIG. 8 is a diagram showing a relationship among a thickness of a fractured layer, a variation in predetermined distance in a viscous material, and a fracture strength of the semiconductor wafer;

FIG. 9 is a schematic cross-sectional view illustrating a state of the semiconductor wafer in step S5;

FIG. 10 is a schematic cross-sectional view illustrating a state of the semiconductor wafer in step S6;

FIG. 11 is a flowchart showing a method of manufacturing a semiconductor device according to Embodiment 2;

FIG. 12 is a schematic cross-sectional view illustrating a state of a semiconductor wafer in step S8; and

FIG. 13 is a schematic cross-sectional view illustrating a state of the semiconductor wafer in step S10.

### DESCRIPTION OF THE PREFERRED EMBODIMENTS

### Embodiment 1

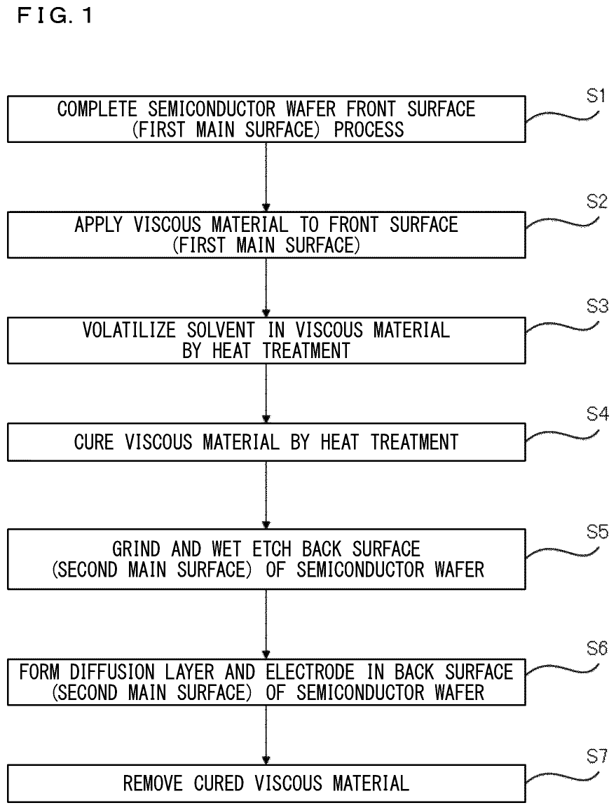

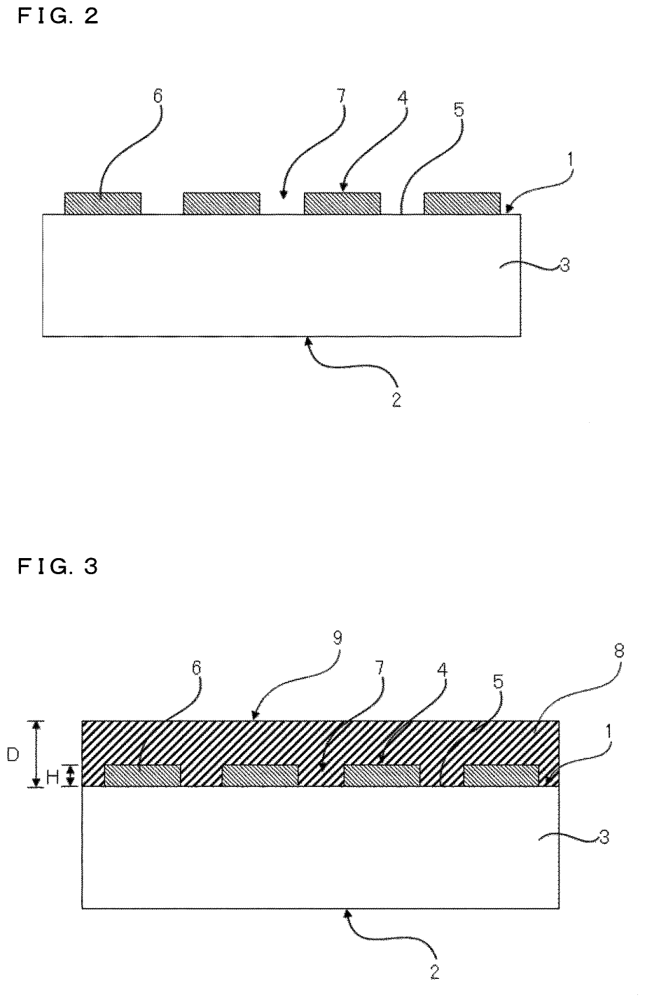

FIG. 1 is a flowchart showing a method of manufacturing a semiconductor device according to Embodiment 1 of the present invention. Turning now to an overview of the manufacturing method, a first main surface (hereinafter also referred to as a “front surface”) of a semiconductor wafer has asperities thereon due to a transistor structure and the like, and a viscous material is applied to the front surface having the asperities thereon and is then cured. After curing of the viscous material, a second main surface (hereinafter also referred to as a “back surface”) of the semiconductor wafer opposite the first main surface is thinned. During thinning, the front surface of the semiconductor wafer is protected by the viscous material. After thinning, the viscous material on the front surface is removed through formation of a diffusion layer in the back surface and the like. FIG. 2 illustrates a cross section of a semiconductor wafer 3 having a front surface 1 having asperities 4 thereon due to a transistor structure and the like. FIG. 3 illustrates a cross section of the semiconductor wafer 3 after curing of a viscous material 8.

The method of manufacturing the semiconductor device according to the present embodiment will be described in detail next with reference to the flowchart shown in FIG. 1, the cross-sectional views illustrated in FIGS. 2 and 3, and the like.

In step S1, as illustrated in FIG. 2, the semiconductor wafer 3 having the front surface 1 and the back surface 2 opposite the front surface 1 is prepared, and asperities 4 are formed on the front surface 1 due to the transistor structure, electrodes, and the like to complete a front surface wafer process. A reference surface 5 corresponding to the front surface 1 of the semiconductor wafer 3 orthogonal to a direction of a thickness on a side of the front surface 1 and projections 6, such as the transistor structure and the electrodes, from the reference surface 5 constitute the asperities 4, and recesses 7 are formed between the projections 6.

In step S2, as illustrated in FIG. 3, the viscous material 8 is directly applied to the front surface 1 of the semiconductor wafer 3. The viscous material 8 is a thermosetting resin, such as a polyimide resin, an ultraviolet curing resin, such as an epoxy resin, and the like, is a liquidity material, and is cured by heating, ultraviolet irradiation, and the like. An example in which the thermosetting resin is used will be described in the present embodiment.

In step S3, the semiconductor wafer 3 is heated from a back side thereof using a heating means, such as an unillustrated hot plate, to volatilize a solvent contained in the viscous material 8. Heating conditions are 150° C. for three minutes, for example.

In step S4, the semiconductor wafer 3 is put into an unillustrated heating furnace to cure the viscous material 8. Heating conditions are 300° C. for 60 minutes, for example. The viscous material 8 is thereby cured.

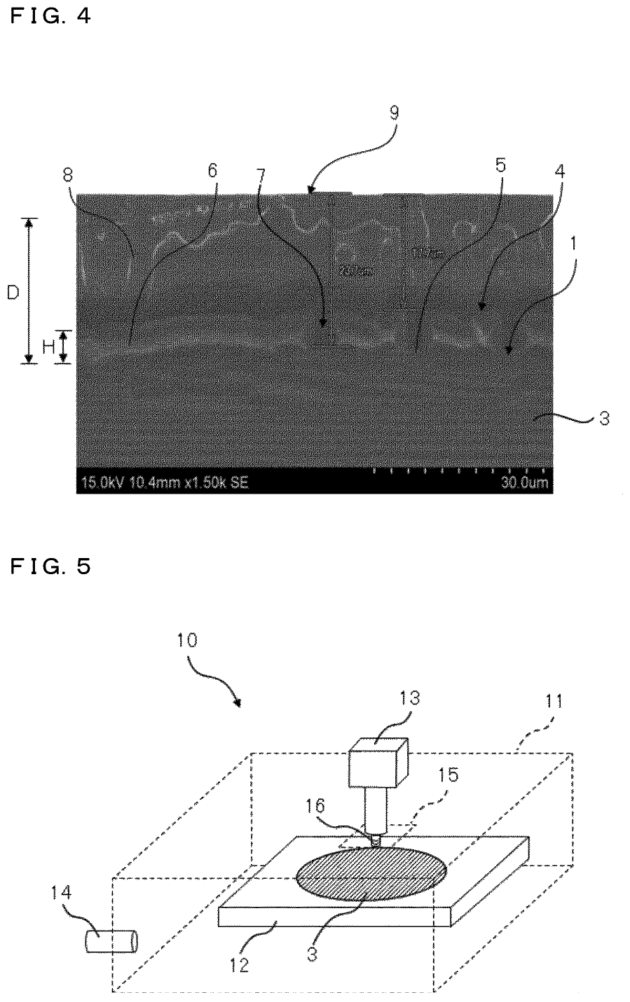

FIG. 4 is a scanning electron microscopy image showing a cross section of the semiconductor wafer 3 with the viscous material 8 being cured. An application amount of the viscous material 8 is set so that a distance D between the reference surface 5 and a surface 9 of the viscous material 8 is greater than a height difference (a height of the projections 6 from the reference surface 5) H of the asperities 4. In the semiconductor wafer 3 shown in FIG. 4, the distance D between the reference surface 5 and the surface 9 of the viscous material 8 is 23.7 μm, the height H of the projections 6 from the reference surface 5 is 23.7 μm−17.7 μm=6.0 μm, and a ratio D/H is approximately 3.9. As for hardness, the viscous material 8 after curing preferably has a modulus of elasticity of 2 GPa or less at which the viscous material 8 is not deformed by pressure applied to the semiconductor wafer 3 in a step of grinding the back surface 2, which will be described below. The distance D is measured from cross-sectional images (scanning electron microscopy images) at a plurality of locations of the semiconductor wafer 3 after curing of the viscous material 8, for example.

One example of an apparatus to apply the viscous material 8 to the front surface 1 of the semiconductor wafer 3 will be shown herein. FIG. 5 is a schematic external perspective view of an application apparatus 10. A housing 11 of the application apparatus 10 is indicated in dashed lines, and an internal configuration of the application apparatus 10 is indicated in solid lines in FIG. 5 for ease of understanding of an interior of the application apparatus 10. The application apparatus 10 includes the housing 11, an application stage 12 provided in the housing 11, an application unit 13 disposed to face the application stage 12, and an air outlet 14 to exhaust air in the housing 11 to an outside.

The application stage 12 is disposed horizontally, and the semiconductor wafer 3 is mounted on the application stage 12 with the front surface 1 of the semiconductor wafer 3 facing upward. The application stage 12 is configured to be horizontally movable by an unillustrated actuator and the like. An upper surface of the housing 11 has an opening 15 at a location where the opening 15 faces the application stage 12, and one side surface of the housing 11 has the air outlet 14.

The application unit 13 is an application apparatus in a dispenser scheme to perform dispensing by gas pressure and the like, and a lower leading end of the application unit 13 extends through the opening 15 from above and is located in the housing 11. A discharge portion 16 to discharge the viscous material 8 filling a syringe is provided at the lower leading end of the application unit 13. The viscous material 8 is discharged from the discharge portion 16 onto the front surface 1 of the semiconductor wafer 3 mounted on the application stage 12.

Operation of the application unit 13 will be described. The viscous material 8 is dispensed from the discharge portion 16 with the semiconductor wafer 3 being mounted on the application stage 12, the application stage 12 is then horizontally moved, and the viscous material 8 is discharged from the discharge portion 16 upon arrival of an unapplied portion of the front surface 1 of the semiconductor wafer 3 immediately below the discharge portion 16. Such operation is repeatedly performed to apply the viscous material 8 to the front surface 1 of the semiconductor wafer 3.

By using the dispenser scheme in which discharge pressure is adjustable in response to viscosity of the viscous material 8 as described above, the viscous material 8 can be applied in response to a pattern of the asperities 4 with accuracy. As a result, flatness of the surface 9 of the viscous material 8 can be increased, and a usage of the viscous material 8 can be controlled. The application stage 12 and the discharge portion 16 of the application unit 13 are covered with the housing 11, and exhaustion from the air outlet 14 forms an airflow from the opening 15 to the air outlet 14, so that turbulence of the airflow caused during driving of the application stage 12 can be reduced. As a result, a variation in thickness (distance D) of the viscous material 8 can be suppressed.

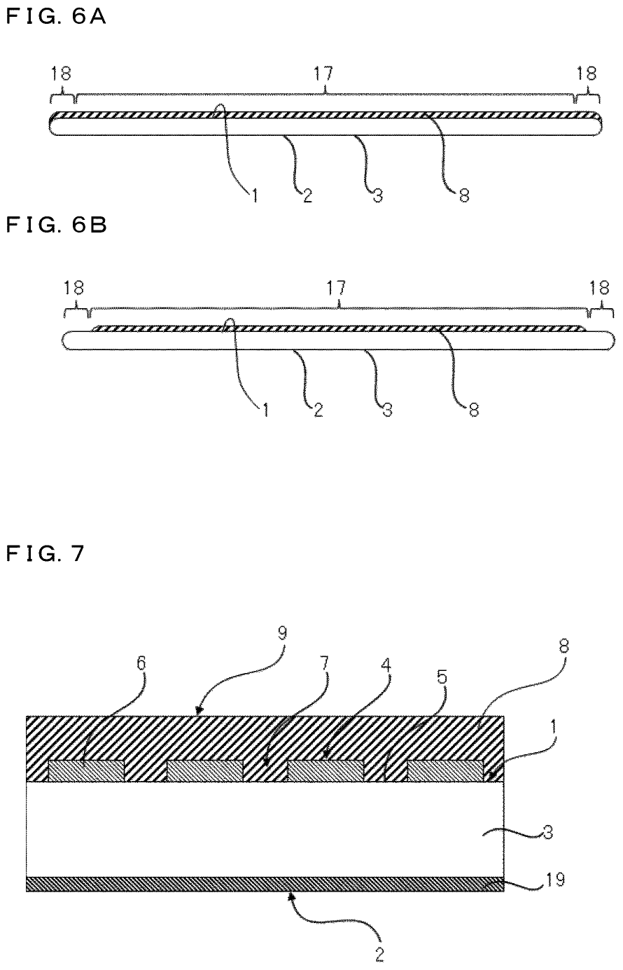

FIGS. 6A and 6B are schematic cross-sectional views each illustrating the semiconductor wafer 3 as a whole to which the viscous material 8 has been applied. The front surface 1 of the semiconductor wafer 3 includes an asperity region 17 having the asperities 4 and a non-asperity region 18 located at an outer peripheral end of the semiconductor wafer 3 and not having the asperities 4. The viscous material 8 may be applied to the front surface 1 of the semiconductor wafer 3 as a whole, that is, to the asperity region 17 and the non-asperity region 18 as illustrated in FIG. 6A or may be applied to the asperity region 17 and be not applied to the non-asperity region 18 as illustrated in FIG. 6B.

When the viscous material 8 is applied to the front surface 1 of the semiconductor wafer 3 as a whole, the outer peripheral end of the semiconductor wafer 3 can be protected, so that breakage or chipping at the outer peripheral end of the semiconductor wafer 3 can be suppressed.

When the viscous material 8 is not applied to the non-asperity region 18, the usage of the viscous material 8 can be suppressed while the asperity region 17 is protected by the viscous material 8. The need for removal of the viscous material 8 in the non-asperity region 18 is eliminated, so that entry of foreign matter due to a fall of the cured viscous material 8 in a step of carrying the semiconductor wafer 3 and in other processing steps can be suppressed.

In step S5, the back surface 2 of the semiconductor wafer 3 is thinned. Mechanical grinding is performed as thinning. FIG. 7 illustrates a cross section of the semiconductor wafer 3 having been thinned in step S5. Due to thinning described above, a fractured layer 19 is formed in the back surface 2 of the semiconductor wafer 3 as illustrated in FIG. 7. The fractured layer 19 may chemically be ground by wet etching using mixed acid containing hydrofluoric acid and acetic acid as necessary.

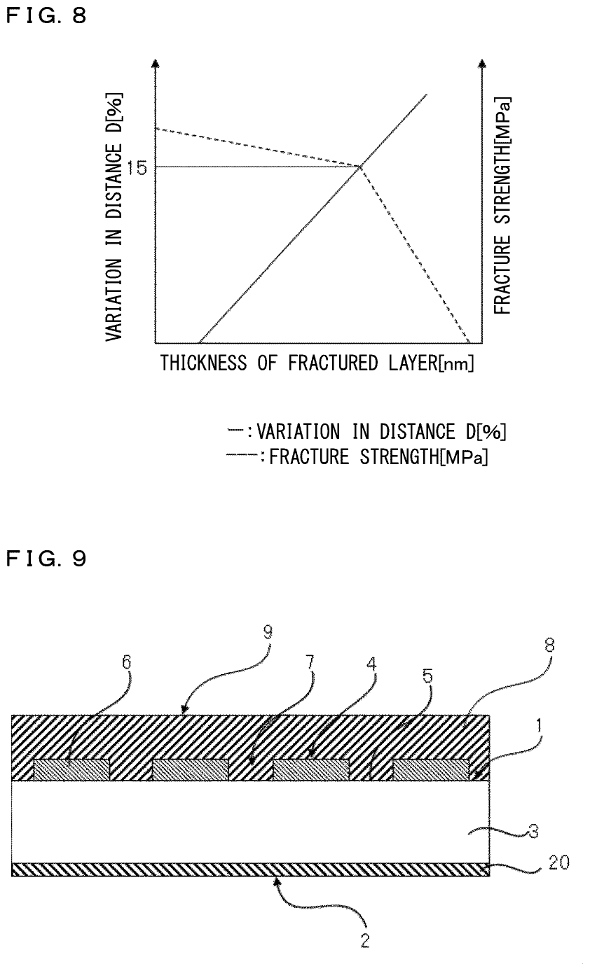

FIG. 8 shows a relationship among a thickness of the fractured layer 19, a variation in distance D between the surface 9 of the viscous material 8 and the reference surface 5, and a fracture strength of the semiconductor wafer 3. The inventors have found that, as illustrated in FIG. 8, reduction in fracture strength of the semiconductor wafer 3 can be suppressed when the variation in distance D is 15% or less of an in-plane average A of the distance D in the surface 9 of the viscous material 8, in other words, when a difference between the distance D and the in-plane average A is 15% or less of the in-plane average A. The in-plane average A is herein an average value of the distance D measured at a plurality of points at random locations in the surface 9 of the viscous material 8. Specifically, when the distance D is 15% or less of the in-plane average A, the fracture strength of the semiconductor wafer 3 is gradually reduced with increasing variation in distance D, but the fracture strength is maintained to the extent that cracking and breakage of the semiconductor wafer 3 during manufacture of the semiconductor device can be suppressed. On the other hand, when the variation in distance D exceeds 15% of the in-plane average A, the thickness of the fractured layer 19 increases, and the fracture strength of the semiconductor wafer 3 is reduced.

Based on the above-mentioned findings, an attempt to set the variation in distance D between the surface 9 of the cured viscous material 8 and the reference surface 5 to 15% or less of the in-plane average A of the distance D to improve the fracture strength of the semiconductor wafer 3 is made in the invention of the present disclosure.

The viscous material 8 is applied while gas pressure of the application unit 13 and the like are controlled so that the variation in distance D between the surface 9 of the viscous material 8 and the reference surface 5 is 15% or less of the in-plane average A of the distance D, so that the thickness of the fractured layer 19 can be suppressed to increase the fracture strength of the semiconductor wafer 3. The need for stacking of a support base, grinding of a resin surface, and the like having conventionally been performed is thus eliminated. In particular, in stacking the support base, the support base is required to be stacked parallel to the semiconductor wafer, taking effort to position and hold the support base. Grinding time of the fractured layer 19 and a usage of a chemical solution in a case of chemical grinding can also be reduced. In view of the foregoing, the method of manufacturing the semiconductor device according to the present embodiment enables reduction in cost of manufacture of the semiconductor device compared with a conventional method.

FIG. 9 illustrates a cross section of the semiconductor wafer 3 with a diffusion layer 20 being formed in step S6. In step S6, as illustrated in FIG. 9, the diffusion layer 20 is formed in the back surface 2 of the semiconductor wafer 3 by ion implantation and the like, and an electrode is formed by sputtering.

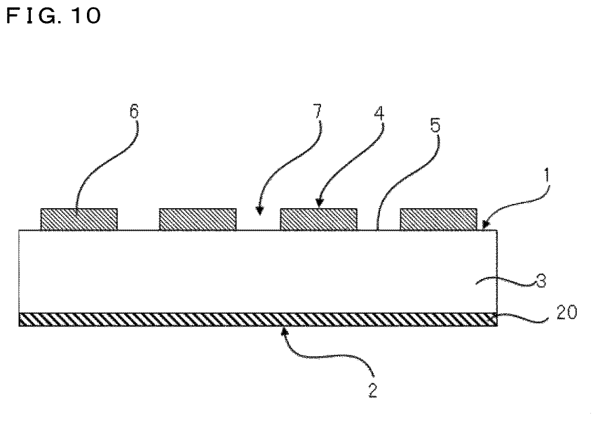

FIG. 10 illustrates a cross section of the semiconductor wafer 3 with the viscous material 8 being removed in step S7. In step S7, as illustrated in FIG. 10, the viscous material 8 is removed from the front surface 1 of the semiconductor wafer 3. A method of removing the viscous material 8 includes the following methods. For example, an organic solvent is dripped onto the surface 9 of the viscous material 8 to dissolve and remove the viscous material 8. For example, the viscous material 8 is removed by so-called ashing in which the viscous material 8 is irradiated with plasma containing oxygen to be carbonized and is removed. For example, the viscous material 8 is removed using a mixed solution containing sulfuric acid and a hydrogen peroxide solution. When the removal method using the mixed solution is performed, plasma irradiation described above may also be performed. While there are various methods of removing the viscous material 8, the viscous material 8 is assumed to be removed using the organic solvent in the present embodiment.

In view of the foregoing, according to the method of manufacturing the semiconductor device according to the present embodiment, the fracture strength of the semiconductor wafer 3 can be increased by suppressing the thickness of the fractured layer 19, and the cost of manufacture of the semiconductor device can be reduced compared with that in the conventional method.

### Embodiment 2

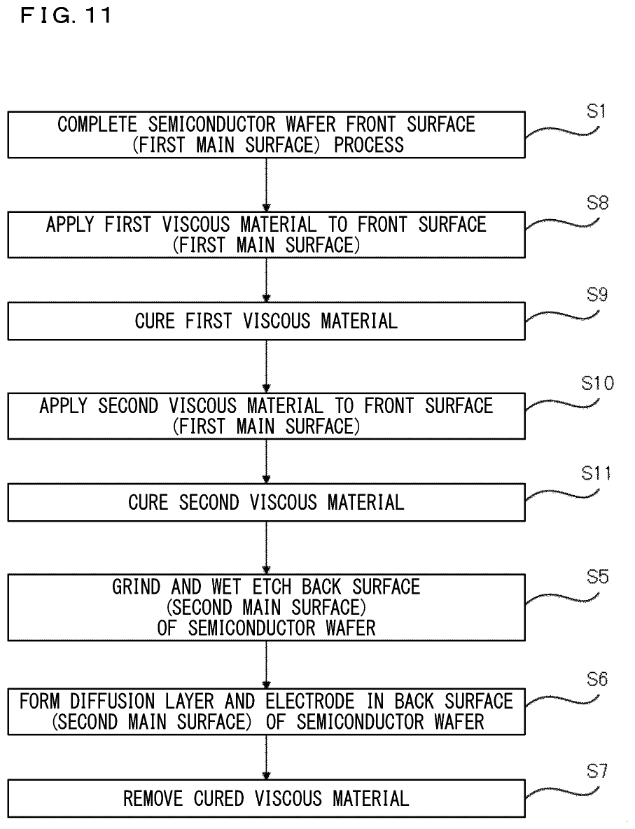

FIG. 11 is a flowchart showing a method of manufacturing a semiconductor device according to Embodiment 2. In the method of manufacturing the semiconductor device according to the present embodiment, similar components and steps to those in the manufacturing method according to Embodiment 1 bear the same reference signs as those of the similar components and steps, and differences from Embodiment 1 will mainly be described below.

As shown in FIG. 11, the manufacturing method according to the present embodiment includes, in a manufacturing flow according to Embodiment 1 (FIG. 1), steps S8 to S11 between the front surface wafer process (step S1) and the step of grinding and wet etching the back surface (step S5). Specifically, a step of applying a first viscous material (step S8), a step of curing the first viscous material (step S9), a step of applying a second viscous material (step S10), and a step of curing the second viscous material (step S11) are performed. Each of the steps will be described below.

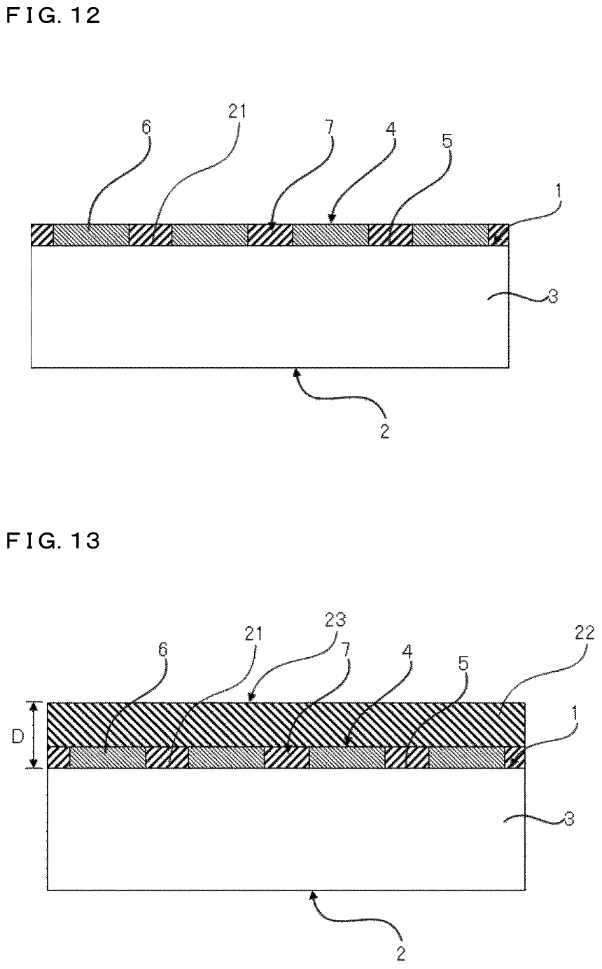

FIG. 12 illustrates a cross section of the semiconductor wafer 3 with a first viscous material 21 being applied in step S8. In step S8, as illustrated in FIG. 12, the first viscous material 21 is applied mainly to the recesses 7 of the asperities 4 on the front surface 1 of the semiconductor wafer 3. The recesses 7 are thereby filled with the first viscous material 21 to level out a surface of the asperities 4, so that flatness can be improved. Use of the application unit 13 in the dispenser scheme allows for application of the first viscous material 21 to the recesses 7 with high positioning accuracy, contributing to improvement in flatness of the surface of the asperities 4. Furthermore, an application amount of the first viscous material 21 can be controlled, so that a usage of the first viscous material 21 can be suppressed. The first viscous material 21 may not necessarily be applied using the application unit 13 and may be applied using a spin coater (not illustrated), for example. It is, however, preferable to use the dispenser scheme with high positioning accuracy as application is performed to the recesses 7 of the asperities 4 having a relatively small area.

The first viscous material 21 is a thermosetting resin as with the viscous material 8 according to Embodiment 1. The first viscous material 21 is not limited to the thermosetting resin and may be an ultraviolet curing resin and the like.

In step S9, the first viscous material 21 is cured. Specifically, thermal curing is performed by a similar method to that in steps S3 and S4 according to Embodiment 1.

FIG. 13 illustrates a cross section of the semiconductor wafer 3 with a second viscous material 22 being applied in step S10. In step S10, as illustrated in FIG. 13, the second viscous material 22 different from the first viscous material 21 is applied to the front surface 1 of the semiconductor wafer 3 on which the first viscous material 21 has been cured. A method of applying the second viscous material 22 is not particularly limited, but the second viscous material 22 is preferably applied using the spin coater. Use of the spin coater allows for a smooth spread of the second viscous material 22 over the leveled-out surface of the asperities 4 from a central portion to a peripheral edge portion of the semiconductor wafer 3 and thus suppresses application time and improves production efficiency.

The second viscous material 22 is a thermosetting resin as with the viscous material 8 according to Embodiment 1. The second viscous material 22 is not limited to the thermosetting resin and may be an ultraviolet curing resin and the like.

The first viscous material 21 preferably has a higher viscosity than the second viscous material 22. In this case, the first viscous material 21 having a higher viscosity is less likely to spread in the recesses 7 of the asperities 4 and is likely to remain in the recesses 7, so that flatness of the asperities 4 can be increased, and flatness of a surface 23 of the second viscous material 22 can be increased as the second viscous material 22 having a lower viscosity spreads.

In step S11, the second viscous material 22 is cured. Specifically, thermal curing is performed by a similar method to that in steps S3 and S4 according to Embodiment 1.

As described above, the second viscous material 22 is applied to the surface of the asperities 4 leveled out by the first viscous material 21, so that the second viscous material 22 can be formed to have the surface having high flatness. As a result, a variation in distance D between the surface 23 of the second viscous material 22 and the reference surface 5 can be suppressed to 15% or less of the in-plane average A of the distance D in the front surface 1 of the semiconductor wafer 3.

While preferred embodiments and the like have been described above, various types of modification and replacement can be added to the above-mentioned embodiments and the like without being limited to those in the above-mentioned embodiments and the like and without departing from a scope described in the claims.

While the viscous material 8 is not applied to the non-asperity region 18 of the front surface 1 of the semiconductor wafer 3 in Embodiment 1, a region to which the viscous material 8 is applied is not limited to this region, the viscous material may be applied to the non-asperity region 18, and a thickness of the viscous material applied to the non-asperity region 18 may be smaller than a thickness of the viscous material applied to the asperity region 17.

While the first viscous material and the second viscous material are materials having different viscosities in Embodiment 2, they may be materials having the same viscosity.

While the first viscous material 21 and the second viscous material 22 differ in viscosity in Embodiment 2, properties differing between the first viscous material 21 and the second viscous material 22 are not limited to viscosity, and the first viscous material 21 and the second viscous material 22 may differ in cure shrinkage, hardness after curing, chemical resistance, and the like. When they differ in cure shrinkage, the first viscous material 21 preferably has a greater cure shrinkage than the second viscous material 22. When they differ in hardness after curing, the first viscous material 21 preferably has a greater hardness than the second viscous material 22.

While the first viscous material and the second viscous material are separately cured in Embodiment 2, time to cure the first viscous material and the second viscous material is not limited to that in this example, and the second viscous material may be applied after application of the first viscous material, and they may be cured at one time, for example.

While the viscous material is applied one or two times in Embodiments 1 and 2, the number of times the viscous material is applied is not limited to one or two, and the viscous material may be applied three or more times.

Various aspects of the present disclosure will collectively be described below as appendices.

### APPENDIX 1

A method of manufacturing a semiconductor device, the method comprising:
an application step of applying a viscous material to a first main surface of a wafer, the first main surface having an asperity thereon, the wafer having the first main surface and a second main surface opposite the first main surface;
a curing step of curing the viscous material; and
a grinding step of grinding the second main surface of the wafer, wherein a reference surface corresponding to a surface of the wafer orthogonal to a direction of a thickness of the wafer and a projection from the reference surface constitute the asperity on the first main surface, and
a variation in distance between a surface of the cured viscous material and the reference surface is 15% or less of an in-plane average of the distance in the first main surface.

### APPENDIX 2

A method of manufacturing a semiconductor device, the method comprising:
an application step of applying a viscous material to a first main surface of a wafer, the first main surface having an asperity thereon, the wafer having the first main surface and a second main surface opposite the first main surface;
a curing step of curing the viscous material; and
a grinding step of grinding the second main surface of the wafer, wherein
the application step includes a first application step of applying the viscous material to a recess of the asperity and a second application step of applying the viscous material to the first main surface after the first application step.

### APPENDIX 3

The method of manufacturing the semiconductor device according to Appendix 2, wherein
a reference surface corresponding to a surface of the wafer orthogonal to a direction of a thickness of the wafer and a projection from the reference surface constitute the asperity on the first main surface, and
a variation in distance between a surface of the cured viscous material and the reference surface is 15% or less of an in-plane average of the distance in the first main surface.

### APPENDIX 4

The method of manufacturing the semiconductor device according to Appendix 2 or 3, wherein
the viscous material applied in the first application step has a higher viscosity than the viscous material applied in the second application step.

### APPENDIX 5

The method of manufacturing the semiconductor device according to any one of Appendices 2 to 4, wherein
the viscous material is applied using a dispenser in the first application step, and
the viscous material is applied using a spin coater in the second application step.

### APPENDIX 6

The method of manufacturing the semiconductor device according to any one of Appendices 1 to 5, wherein
the first main surface includes an asperity region as a region of the asperity and a non-asperity region located outside the asperity region, and
in the application step, the viscous material is applied to the asperity region and is not applied to the non-asperity region, or the viscous material is applied so that a thickness of the viscous material applied to the non-asperity region is smaller than a thickness of the viscous material applied to the asperity region.

### APPENDIX 7

A semiconductor device manufacturing apparatus comprising:
a stage on which a second main surface of a wafer is mounted, the wafer having a first main surface having an asperity thereon and the second main surface opposite the first main surface;
a dispenser disposed to face the stage and applying a viscous material to the first main surface with the wafer being mounted on the stage; and
a housing covering a discharge portion of the dispenser and the stage, having an opening through which the discharge portion is inserted to face the stage, and having an air outlet at a different location from the opening.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device, the method comprising:
applying a viscous material to a first main surface of a wafer, the first main surface having an asperity thereon, the wafer having the first main surface and a second main surface opposite the first main surface;
curing the viscous material; and
grinding the second main surface of the wafer, wherein
a reference surface corresponding to a surface of the wafer orthogonal to a direction of a thickness of the wafer and a projection from the reference surface constitute the asperity on the first main surface, and
a variation in distance between a surface of the cured viscous material and the reference surface is 15% or less of an in-plane average of the distance in the first main surface.

2. The method of manufacturing the semiconductor device according to claim 1, wherein
the first main surface includes an asperity region as a region of the asperity and a non-asperity region located outside the asperity region, and
in the step of applying the viscous material, the viscous material is applied to the asperity region and is not applied to the non-asperity region, or the viscous material is applied so that a thickness of the viscous material applied to the non-asperity region is smaller than a thickness of the viscous material applied to the asperity region.

3. A method of manufacturing a semiconductor device, the method comprising:
applying a viscous material to a first main surface of a wafer, the first main surface having an asperity thereon, the wafer having the first main surface and a second main surface opposite the first main surface;
curing the viscous material; and
grinding the second main surface of the wafer, wherein
the step of applying the viscous material includes a first application step of applying the viscous material to a recess of the asperity and a second application step of applying the viscous material to the first main surface after the first application step.

4. The method of manufacturing the semiconductor device according to claim 3, wherein
a reference surface corresponding to a surface of the wafer orthogonal to a direction of a thickness of the wafer and a projection from the reference surface constitute the asperity on the first main surface, and
a variation in distance between a surface of the cured viscous material and the reference surface is 15% or less of an in-plane average of the distance in the first main surface.

5. The method of manufacturing the semiconductor device according to claim 3, wherein
the viscous material applied in the first application step has a higher viscosity than the viscous material applied in the second application step.

6. The method of manufacturing the semiconductor device according to claim 3, wherein
the viscous material is applied using a dispenser in the first application step, and
the viscous material is applied using a spin coater in the second application step.

7. The method of manufacturing the semiconductor device according to claim 3, wherein
the first main surface includes an asperity region as a region of the asperity and a non-asperity region located outside the asperity region, and
in the step of applying the viscous material, the viscous material is applied to the asperity region and is not applied to the non-asperity region, or the viscous material is applied so that a thickness of the viscous material applied to the non-asperity region is smaller than a thickness of the viscous material applied to the asperity region.

8. A semiconductor device manufacturing apparatus comprising:
a stage on which a second main surface of a wafer is mounted, the wafer having a first main surface having an asperity thereon and the second main surface opposite the first main surface;
a dispenser disposed to face the stage and applying a viscous material to the first main surface with the wafer being mounted on the stage; and
a housing covering a discharge portion of the dispenser and the stage, having an opening through which the discharge portion is inserted to face the stage, and having an air outlet at a different location from the opening.
